(19) United States
(12) Patent Application Publication
(10) Pub. No.: US 2009/0174003 A1
(43) Pub. Date: Jul. 9, 2009

(54) DUAL WORK FUNCTION DEVICE WITH STRESSOR LAYER AND METHOD FOR MANUFACTURING THE SAME

(75) Inventors: Shou-Zen Chang, Jhudong Township (TW); Thomas Y. Hoffman, Leuven (BE); Geoffrey Pourtois, Villers-la-Ville (BE); Hong Yu Yu, Singapore (SG)

Correspondence Address: KNOBBE MARTENS OLSON & BEAR LLP, 2040 MAIN STREET, FOURTEENTH FLOOR, IRVINE, CA, 92614, US

(73) Assignees: Interuniversitair Microelektronica Centrum vzw (IMEC), Leuven (BE); Taiwan Semiconductor Manufacturing Company, Ltd. (TSMC), HsinChu (TW)

(21) Appl. No.: 12/269,754

(22) Filed: Nov. 12, 2008

Related U.S. Application Data
(60) Provisional application No. 60/987,712, filed on Nov. 13, 2007.

(30) Foreign Application Priority Data
Jun. 10, 2008 (EP) EP 08157942.7

(51) Int. Cl. H01L 27/092; H01L 21/28

(52) U.S. Cl. 257/369; 438/586; 257/E27.062; 438/652; 257/E21.19

(57) ABSTRACT

A method for manufacturing a dual work function semiconductor device is disclosed. In one aspect, the method relates to providing a substrate with a first and a second region. A gate dielectric is formed overlying the first and the second region. A metal gate layer is formed overlying the gate dielectric on the first and the second region. The metal gate layer has a first (as-deposited) work function that can be modified upon inducing strain thereon. The method further relates to selecting a first strain which induces a first pre-determined work function shift (ΔWF1) in the first (as-deposited) work function of the metal gate layer on the first region and selectively forming a first strained conductive layer overlying the metal gate layer on the first region, the first strained conductive layer exerting the selected first strain on the metal gate layer.

### CROSS REFERENCE TO RELATED APPLICATIONS

This application claims priority under 35 U.S.C. § 119(e) to U.S. provisional patent application 60/987,712 filed on Nov. 13, 2007, which application is hereby incorporated by reference in its entirety.

### BACKGROUND OF THE INVENTION

1. Field of the Invention

The present invention is related to methods of manufacturing CMOS devices. Particularly, the invention is related to CMOS-devices having a gate stack comprising a metal gate electrode.

2. Description of the Related Technology

Scaling MOSFET transistors to improve performance results in higher gate leakage as the SiO2 gate dielectric becomes thinner. To address this issue, SiO2 gate dielectric has been replaced with high-k materials (k-value>kSiO2). With the introduction of the high-k materials a new problem arose, namely the Fermi level pinning. Fermi level pinning effect takes place at the polysilicon (polySi)/metal oxide interface and causes high threshold voltages in MOSFET devices.

A known solution to this problem is the introduction of metal gates. However, it has been proven difficult to identify band-edge metals (metals with either a n-type or a p-type work function (WF)) that are compatible with the conventional CMOS manufacturing process. CMOS can be made using dual metal gates with single or dual dielectrics. In either case, a selective removal of one of the metal gates is necessary and adds substantial complexity and costs to the manufacturing process.

Another known solution for CMOS manufacturing is to use fully silicided (FUSI) gates, without a selective removal of electrode or gate dielectric. However, FUSI gates require different silicide phases on nMOS and pMOS. on small devices, the phase or composition of the FUSI gates tends to distribute unevenly, resulting in severe within-wafer threshold voltage (Vₜ) non-uniformity.

### SUMMARY OF CERTAIN INVENTIVE ASPECTS

One inventive aspect discloses a method for manufacturing a dual work function semiconductor device using strained conductive layers for work function tuning.

Another inventive aspect provides a method for manufacturing a dual work function semiconductor device which overcomes at least one of the drawbacks of prior art methods. Still another inventive aspect relates to a dual work function semiconductor device with good performance.

One inventive aspect relates to a method for manufacturing a dual work function semiconductor device comprising: providing a substrate with a first and a second region, forming a gate dielectric overlying the first and the second region, forming a metal gate layer overlying the gate dielectric on the first and the second region, the metal gate layer having a first (as-deposited) work function that can be modified upon inducing strain thereon, selectively forming a first strained conductive layer, overlying the metal gate layer on the first region, the first strained conductive layer exerting a selected first strain on the metal gate layer, thereby inducing a first pre-determined work function shift (ΔWF1) in the first (as-deposited) work function of the metal gate layer on the first region.

The method according to the above, wherein selectively forming a first strained conductive layer comprises: depositing a layer of polysilicon overlying the metal gate layer on the first and the second region, patterning the polysilicon, the metal gate layer and the gate dielectric to form a gate structure on both the first and the second region, forming dielectric spacers covering the sidewalls of the gate structure, performing a replacement gate process on the first region comprising replacing the polysilicon layer on the first region by the first strained conductive layer.

The method according to the above, wherein selectively forming a first strained conductive layer comprises: depositing a first strained conductive layer overlying the metal gate layer on the first and the second region, removing the first strained conductive layer selectively to the metal gate layer on the second region.

The method according to the above, further comprising selectively forming a second strained conductive layer, overlying the metal layer on the second region, the second strained conductive layer exerting a selected second strain on the metal gate layer, thereby inducing a second pre-determined work function shift (ΔWF2) in the first (as deposited) work function of the metal gate layer on the second region.

The method according to the above, further comprising selectively forming a third strained conductive layer overlying the gate structures and the spacers on at least one of the first and the second regions, the third strained conductive layer exerting a selected third strain on the gate structures comprising the metal gate layer, thereby inducing a third pre-determined work function shift (ΔWF3) in the first (as deposited) work function of the metal gate layer, on at least one of the first and the second region, respectively.

The method according to the above, further comprising forming a dielectric layer in contact with the third strained conductive layer on both sides, thereby creating a dielectric-strained metal-dielectric stack (sandwich).

The method according to any of the above, wherein the first region is a NMOS region and the second region is a PMOS region.

The method according to any of the above, wherein the metal gate layer has a mid-gap as-deposited work function (mid-gap defined elsewhere in the specifications) and the first pre-determined work function shift (ΔWF1) and the second pre-determined work function shift (ΔWF2) have opposite signs with respect to the mid-gap.

The method according to any of the above, further comprising performing a thermal treatment after depositing one of the first, the second or the third strained conductive layers, wherein the thermal treatment modifies in a pre-determined way the first, the second and/or the third strain exerted on the metal gate layer and thereby the first, the second and/or the third work function shift induced in the first (as deposited) work function of the metal gate.

The method according to any of the above, wherein the first and the third strained conductive layer are made of the same material.

The method according to any of the above, wherein the substrate comprises Si, Ge, SiGe, SOI, GeOI, III-V materials and combinations thereof.

The method according to any of the above, wherein the gate dielectric layer comprises, SiO₂, SiON, high-k materials and combinations thereof.

The method according to any of the above, wherein the metal gate layer comprises a metal or a metal silicide.

The method according to any of the above, wherein the metal gate layer comprises at least one of the metals selected from the group of Mo, Ru, W, Al and co-sputtered Ni suicides.

The method according to any of the above, wherein the thickness of the metal gate layer is lower than about 10 nm.

The method according to any of the above, wherein the first strained conductive layer comprises metal carbides, metal nitrides, metal silicides or combinations thereof.

The method according to any of the above, wherein the first strained conductive layer is selected from the group of TaxCy, WxCy, TixNy, TaxNy, TiAlN, TaAlN and combinations thereof, wherein x and y are real numbers 0<x, y≦1.

The method according to any of the above, further comprising introducing one or more species selected from the group of C, N and O into the first strained conductive layer. The method according to the above, wherein the second strained conductive layer is selected from the group of TaxCy, WxCy, TixNy, TaxNy, TiAlN, TaAlN and combinations thereof, wherein x and y are real numbers 0<x, y≦1.

The method according to the above, wherein the third strained conductive layer comprises metal carbides, metal nitrides or combinations thereof.

Another inventive aspect relates to a semiconductor device obtainable with the method described in the above.

Another inventive aspect relates to a dual work function semiconductor device, comprising a first transistor on a first substrate region and a second transistor on a second substrate region, comprising each a gate dielectric, the gate dielectric of the first transistor having substantially the same composition and same thickness with the gate dielectric of the second transistor, and a metal gate layer having a first (as-deposited) work function that can be modified upon inducing strain thereon, overlying the gate dielectric, the metal gate layer of the first transistor having substantially the same composition and same thickness with the metal gate layer of the second transistor, the first transistor further comprises a first strained conductive layer overlying the metal gate layer, the first strained conductive layer exerts a selected first strain on the metal gate layer, thereby inducing a first pre-determined work function shift (ΔWF1) in the first (as deposited) work function of the metal gate layer.

The semiconductor device of the above, wherein the second transistor further comprises a second strained conductive layer, overlying the metal layer, the second strained conductive layer exerts a selected second strain on the metal gate layer, thereby inducing a second pre-determined work function shift (ΔWF2) in the first (as deposited) work function of the metal gate layer.

The semiconductor device of the above, further comprising selectively forming a third strained conductive layer overlying the gate structures and the spacers of at least one of the first and the second transistors, the third strained conductive layer exerts a selected third strain on the gate structures comprising the metal gate layer, thereby inducing a third pre-determined work function shift (ΔWF3) in the first (as deposited) work function of the metal gate layer.

The semiconductor device of the above, wherein the first transistor further comprises a dielectric layer contacting both sides of the third strained conductive layer, thereby creating a dielectric-strained metal-dielectric stack (sandwich).

The semiconductor device of the above, wherein the first transistor is a NMOS transistor and the second transistor is a PMOS transistor.

The semiconductor device of the above, wherein the metal gate layer has a mid-gap as-deposited work function and the first pre-determined work function shift (ΔWF1) and the second pre-determined work function shift (ΔWF2) have opposite signs with respect to the mid-gap.

The semiconductor device of the above, wherein the first and the third strained conductive layer are made of the same material.

The semiconductor device of the above, wherein the substrate comprises Si, Ge, SiGe, SOI, GeOI, III-V materials and combinations thereof.

The semiconductor device of the above, wherein the gate dielectric layer comprises, SiO₂, SiON, high-k materials and combinations thereof.

The semiconductor device of the above, wherein the metal gate layer comprises a metal or a metal silicide.

The semiconductor device of the above, wherein the metal gate layer comprises at least one of the metals selected from the group of Mo, Ru, W, Al and co-sputtered Ni silicides.

The semiconductor device of the above, wherein the thickness of the metal gate layer is lower than about 10 nm.

The semiconductor device of the above, wherein the first strained conductive layer comprises metal carbides, metal nitrides, metal silicides or combinations thereof.

The semiconductor device of the above, wherein the first strained conductive layer is selected from the group of TaxCy, WxCy, TixNy, TaxNy, TiAlN, TaAlN and combinations thereof, wherein x and y are real numbers 0<x, y≦1.

The semiconductor device of the above, wherein the first strained conductive layer further comprises one or more species selected from the group of C, N and O.

The semiconductor device of the above, wherein the second strained conductive layer is selected from the group of TaxCy, WxCy, TixNy, TaxNy, TiAlN, TaAlN and combinations thereof, wherein x and y are real numbers 0<x, y≦1.

In another aspect, a method of manufacturing a dual work function semiconductor device is disclosed. The method comprises providing a substrate with a first and a second region. The method further comprises forming a gate dielectric overlying the first and the second region. The method further comprises forming a metal gate layer overlying the gate dielectric on the first and the second region, the metal gate layer having a first as-deposited work function tunable upon inducing stress thereon. The method further comprises selecting a first strain which induces a first pre-determined work function shift (□WF1) in the work function of the metal gate layer on the first region. The method further comprises selectively forming a first strained conductive layer overlying the metal gate layer on the first region, the first strained conductive layer exerting the selected first strain on the metal gate layer.

In another aspect, a method of manufacturing a dual work function semiconductor device is disclosed. The method comprises providing a gate dielectric overlying a first and a second region in a substrate and a metal layer overlying the gate dielectric on the first and the second region, the metal gate layer having an as-deposited work function. The method further comprises forming a first strained conductive layer overlying the metal gate layer on the first region, the first strained conductive layer being selected to exert strain on the metal gate layer thus inducing a first pre-determined work function shift in the work function of the metal gate layer on the first region.

### BRIEF DESCRIPTION OF THE DRAWINGS

All drawings are intended to illustrate some aspects and embodiments of the present invention. The drawings described are only schematic and are non-limiting.

FIG. 1 represents the calculated work function shift (eV) as function of the strain (%) applied on Ta(110) layers, in the case of: ♦ (diamond) uniaxial strain; ▪ (square) biaxial strain.

FIG. 2 represents the influence of the thermal treatment on the stress (dynes/cm2) of a TiN layer on Si: (1) as deposited (2) pre-annealed (300° C.-650° C.) (3) RTP-annealed (650° C.) (4) spike annealed (1050° C.).

FIG. 3 represents the channel stress (MPa) as a function of the film intrinsic stress (GPa) for: ♦ (diamond) metal filling (strained metal layer); ▪ (square) work function (WF) metal with a thickness of 5 nm ▴ (triangle) contact stop etch layer (CESL) with a thickness of 50 nm.

FIGS. 4(a)-(f) represent the different process steps in the manufacturing of a semiconductor device comprising at least one strained conductive layer.

FIG. 5 represents schematically a semiconductor device comprising a first (4) and a second (10) strained conductive layer.

FIG. 6 is a flow chart illustrating the method according to one embodiment.

### DETAILED DESCRIPTION OF CERTAIN ILLUSTRATIVE EMBODIMENTS

The present invention will be described with respect to particular embodiments and with reference to certain drawings but the invention is not limited thereto but only by the claims. Any reference signs in the claims shall not be construed as limiting the scope. The drawings described are only schematic and are non-limiting. In the drawings, the size of some of the elements may be exaggerated and not drawn on scale for illustrative purposes.

Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

The terms deeper or higher are used to denote the relative position of elements in a substrate. With deeper is meant that these elements are more distant from a main surface of the substrate from which side the measurement is to be performed.

Various embodiments of the invention are referring to parameters of the semiconductor device such as threshold voltage, work function (WF), or physical characteristics of the material(s) employed such as (as-deposited) work function, Fermi level etc. The definitions as used through this document are summarized herein below.

In the MOSFET device, the gate requires a threshold voltage (Vt) to render the channel conductive. Complementary MOS processes fabricate both n-channel and p-channel (NMOS and PMOS) transistors. The threshold voltage is influenced by what is called the work function difference. To establish threshold voltage (Vt) values, the work function differences of the respective PMOS and NMOS gate materials (gate stacks) and their corresponding channel regions are independently established trough channel processing and gate processing. In other words, both gate dielectric (including i.e. a host dielectric and different capping layers) and gate electrode (including i.e. at least one metal layer) determine the work function of the gate stack (transistor). Moreover, the gate processing itself (i.e. the sequence of the different steps and/or the thermal treatments applied) may have an influence on the work function of the gate stack (transistor).

The work function of a gate stack (transistor) is a parameter that can be tuned (adjusted/modified) by the choice of the gate dielectric materials, gate electrode materials and by the gate processing performed. On the contrary, the as-deposited work function of the gate electrode (often referred to as metal gate electrode/metal layer) is an intrinsic property of the material. In general, the work function of a certain material (i.e. a metal layer) is a measure of the energy, in electron volts (eV), required to eject an electron in the material outside of a material atom to the vacuum, if the electron were initially at the Fermi level.

For a silicon substrate, the gate electrode of a negative channel MOSFET (or NMOS) transistor has a n-type work function of approximately 4.1 eV (+/−0.3 eV), and the gate electrode of a positive channel MOSFET (or PMOS) transistor has a p-type work function of approximately 5.2 eV (+/−0.3 eV). A typical “mid-gap” material has a work function of approximately 4.6-4.7 eV.

State of the art describes strained layers as well as other strain enhancing techniques (e.g. strained silicon on insulator (SSOI), or SiGe re-growth) that are used in CMOSFET (complementary metal-oxide-semiconductor field effect transistors) technology for enhancing device performance. The induced strain can propagate into the channel, modifying the band diagram and leading to an increase the drive current. The strained layers are either removed, while their benefit is kept due to stress memorization techniques (SMT), or they can be kept and used as e.g. contact etch-stop layer (CESL).

Certain embodiments of the present invention relate to a method for manufacturing a dual work function semiconductor device using strained conductive layers for work function tuning.

The invention will now further be described by a detailed description of several particular embodiments of the invention. It is clear that other embodiments of the invention can be configured according to the knowledge of persons skilled in the art without departing from the true spirit or technical teaching of the invention.

Where, herein, a specific chemical name or formula is given, the material may include non-stoichiometric variations of the stoichiometrically exact formula identified by the chemical name. Lack of numerical subscript by an element in the formula stoichiometrically signifies the number one (1). Variations in the range plus/minus 20% of the exact stoichiometric number are comprised in the chemical name or formula, for the present purposes. Where an algebraic subscript is given, then variations in the range of about plus/minus 20% are comprised relative to the value of each subscript. Such varied values do not necessarily sum to a whole number and this departure is contemplated. Such variations may occur due to either intended selection and control of the process conditions, or due to unintended process variations.

In a first aspect of the current invention a method for manufacturing a dual work function semiconductor device is disclosed, comprising
providing a substrate with a first and a second region,
forming a gate dielectric overlying the first and the second region,
forming a metal gate layer overlying the gate dielectric on the first and the second region, the metal gate layer having a first (as-deposited) work function that can be modified upon inducing strain thereon,
selecting a first strain which induces a first pre-determined work function shift (ΔWF1) in the first (as-deposited) work function of the metal gate layer on the first region, selectively forming a first strained conductive layer, overlying the metal gate layer on the first region, the first strained conductive layer exerting the selected first strain on the metal gate layer.

The gate dielectric can comprise one or more layers of dielectric materials, e.g. SiO2, SiON or high-k dielectric materials.

The gate electrode comprises a metal gate layer overlying the gate dielectric and one or more conductive layers overlying the metal gate layer. The work function of the metal gate layer in contact with the gate dielectric determines the threshold voltage of the device. The metal gate layer can comprise a metal or a co-sputtered metal silicide.

The conductive layers overlying the metal gate layers can be made of metal, polysilicon or silicide. The physical characteristics of the conductive layers (e.g. material, thickness, deposition method) are selected to exert a selected strain on the metal gate layer, thereby inducing a pre-determined work function shift in the work function of the metal gate layer. Advantageously, the conductive layers lower the contact resistance of the gate electrode.

An advantage of the method is that the work function of the metal gate layer is modulated through the introduction of a strained conductive layer. Another benefit of the method is the mobility enhancement introduced by the strained conductive layer due to the stress applied on the channel.

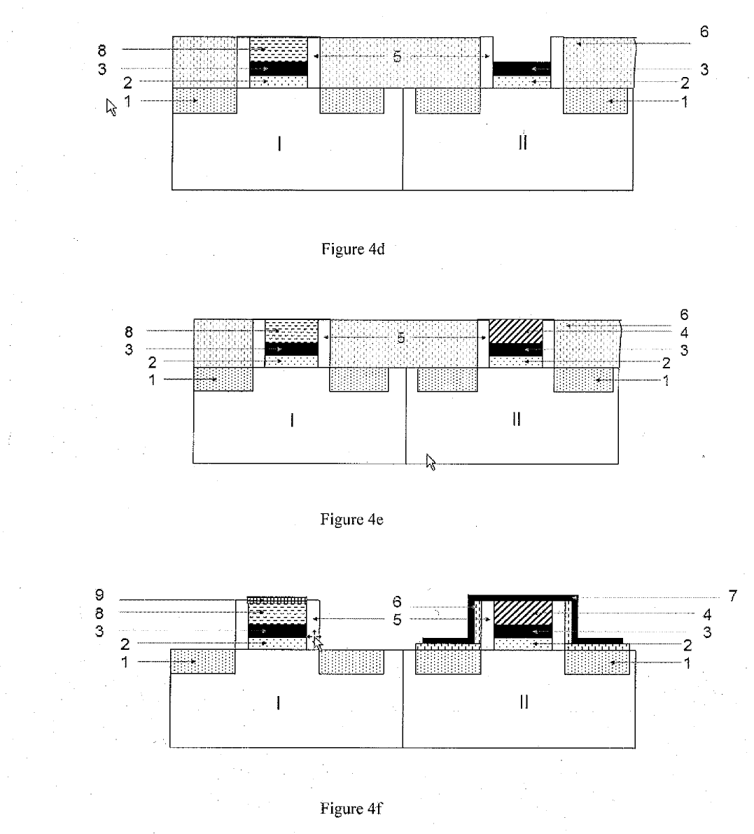

One embodiment of the first aspect of the current invention discloses selectively forming a first strained conductive layer by a gate-last approach as schematically represented in FIG. 4(a)-(e) comprising:
depositing a layer of polysilicon (8) overlying the metal gate layer (3) on the first and the second region
patterning the polysilicon (8), the metal gate (3) layer and the gate dielectric (2) to form a gate structure on both the first and the second region,
forming dielectric spacers (5) covering the sidewalls of the gate structure
performing a replacement gate process on the first region comprising replacing the polysilicon layer (8) on the first region by the first strained conductive layer (4).

Another embodiment of the first aspect of the current invention discloses the step of selectively forming a first strained conductive layer by a “gate-first” approach comprising
depositing a first strained conductive layer overlying the metal gate layer on the first and the second region
removing the first strained conductive layer selectively to the metal gate layer on the second region.

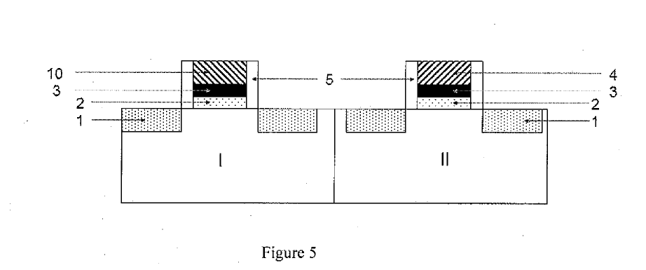

An embodiment of the first inventive aspect discloses a method for manufacturing a dual work function semiconductor device further comprising selecting a second strain which induces a second pre-determined work function shift (ΔWF2) in the first (as deposited) work function of the metal gate layer on the second region, selectively forming a second strained conductive layer (10), overlying the metal layer (3) on the second region, the second strained conductive layer exerting the selected second strain on the metal gate layer. This embodiment is schematically represented in FIG. 5.

Another embodiment of the first aspect discloses a method for manufacturing a dual work function semiconductor device, further comprising selecting a third strain which induces a third pre-determined work function shift (ΔWF3) in the first (as deposited) work function of the metal gate layer, on at least one of the first and the second region, selectively forming a third strained conductive layer (7) overlying the gate structures and the spacers on at least one of the first and the second regions, respectively, the third strained conductive layer exerting the selected third strain on the gate structures comprising the metal gate layer (3). This embodiment is schematically represented in FIG. 4(f).

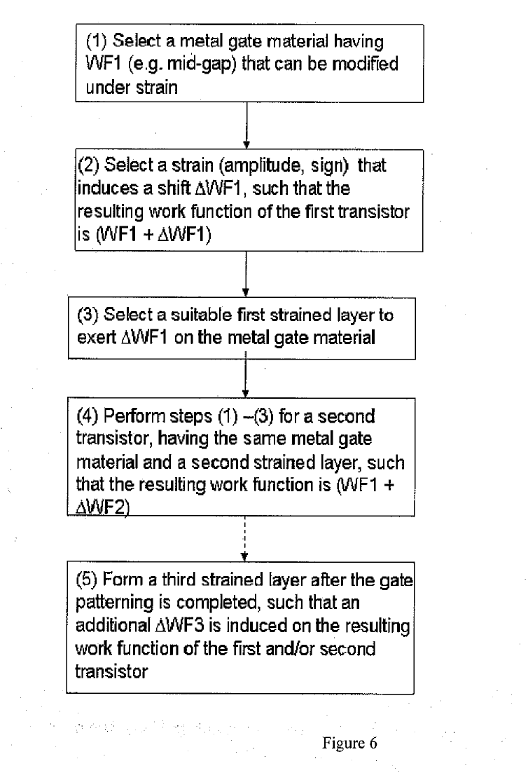

The flow chart in FIG. 6 illustrates schematically the method according to one embodiment.

The first, the second and the third work function shift (ΔWF1, ΔWF2, ΔWF3) may have the same or opposite signs (e.g. both tensile, both compressive, or one tensile and one compressive). In different embodiments the dual work function semiconductor device is a CMOS device comprising a NMOS and a PMOS transistor and the metal gate material has a mid-gap work function. In this case ΔWF1, ΔWF2 have approximately equal amplitudes and opposite signs. The selection of a suitable first, second or third strained layer comprises in each case the selection of a material, a composition, a deposition technique and a thickness suitable to exert the required strain for a pre-determined work function shift.

In one specific embodiment of the first aspect of the current invention, an integration scheme is disclosed wherein a third strained conductive layer (7) is deposited overlying the gate structures and the spacers. The integration scheme comprises the following processes:

(1) standard CMOS processing including active area and shallow trench isolation (STI) definition and well implantation;

(2) forming a gate dielectric e.g. SiO₂, SiON or any high-k material (with a dielectric constant k>kSiO₂);

(3) gate electrode formation and patterning of the gate structures; the gate electrode comprises a metal layer (e.g. Ta, TaN, TaC) or a polysilicon layer to be converted to fully silicided gate (FUSI).

(4) junction formation, spacer definition, source/drain (S/D) rapid thermal anneal (RTA) and Source/Drain silicidation

(5) third strained conductive layer formation overlying the gate structures and the spacers. The third strained conductive layer can comprise e.g. TiN, W.

(6) selective removal of the third strained conductive layer from one of the regions (either NMOS or PMOS). The third strained conductive layer can be kept either on NMOS or on PMOS, depending on the as deposited work function of the metal gate layer and the stress required to modify the as deposited work function with a pre-determined value (shift).

The sign (tensile/compressive) and the intrinsic level of strain (amplitude) which determines the as-deposited work function is a function of the type of metal used, the thickness of the metal layer, the deposition method (e.g. ALD, CVD, AVD, PVD) and temperature budget of the different thermal treatments. Preferably the thickness of the metal layer is between about 0.5 to 10 nm, most preferably between about 5 nm to 10 nm.

Advantageously, the third strained conductive layer (7) can be sandwiched in between two dielectric layers. The dielectric layers improve the adhesion of the third strained conductive layer and avoids the leakage path generation.

In another embodiment of the first aspect of the current invention elements like C, N, or O can be incorporated during deposition or post-deposition (e.g. by implantation, plasma-doping) into the first, second and/or third strained conductive layer.

In different embodiments of the first aspect of the current invention a method is disclosed further comprising performing a thermal treatment after depositing one of the first (4), the second (10) or the third (7) strained conductive layers, wherein the thermal treatment modifies the first, the second and/or the third strain exerted on the metal gate layer (3) and thereby the first, the second and/or the third work function shift induced in the first (as deposited) work function of the metal gate.

In a second aspect of the current invention a dual work function semiconductor device is disclosed, comprising
a first transistor on a first substrate region and a second transistor on a second substrate region, comprising:
a gate dielectric (2), the gate dielectric of the first transistor having substantially the same composition and same thickness with the gate dielectric of the second transistor, and
a metal gate layer (3) having a first (as-deposited) work function that can be modified upon inducing strain thereon, overlying the gate dielectric, the metal gate layer of the first transistor having substantially the same composition and same thickness with the metal gate layer of the second transistor,
the first transistor further comprises a first strained conductive layer (4) overlying the metal gate layer, the first strained conductive layer exerts a selected first strain on the metal gate layer, thereby inducing a first pre-determined work function shift (ΔWF1) in the first (as deposited) work function of the metal gate layer.

In one embodiment of the second aspect, the second transistor further comprises a second strained conductive layer (10), overlying the metal layer (3), the second strained conductive layer exerts a selected second strain on the metal gate layer, thereby inducing a second pre-determined work function shift (ΔWF2) in the first (as deposited) work function of the metal gate layer.

In another embodiment of the second aspect, a semiconductor device is disclosed further comprising selectively forming a third strained conductive layer (7) overlying the gate structures and the spacers of at least one of the first and the second transistors, the third strained conductive layer exerts a selected third strain on the gate structures comprising the metal gate layer, thereby inducing a third pre-determined work function shift (ΔWF3) in the first (as deposited) work function of the metal gate layer.

In a further embodiment of the second aspect the first, the second, and/or the third strained conductive layer further comprise one or more species selected from the group of C, N and O.

In yet another embodiment of the second aspect, the first transistor further comprises a dielectric layer contacting both sides of the third strained conductive layer, thereby creating a dielectric-strained metal-dielectric stack (sandwich).

In different embodiments of the current invention, the first transistor is a NMOS transistor and the second transistor is a PMOS transistor.

In other embodiments of the current invention the first transistor is a PMOS transistor and the second transistor is a NMOS transistor.

In specific embodiments of the current invention, the metal gate layer (3) has a mid-gap as-deposited work function, while the first pre-determined work function shift (ΔWF1) and the second pre-determined work function shift (ΔWF2) have opposite signs with respect to the mid-gap.

In other embodiments of the invention the first transistor and the second transistor are both NMOS, or both PMOS transistors with different work functions.

In one particular embodiment of the current invention, the first strained conductive layer (4) and the third strained conductive layer (7) are made of the same material.

In certain embodiments of the current invention the substrate comprises Si, Ge, SiGe, SOI, GeOI, III-V materials and combinations thereof.

In certain embodiments of the current invention the gate dielectric layer (2) comprises, SiO₂, SiON, high-k materials and combinations thereof.

In certain embodiments of the current invention the metal gate layer (3) comprises a metal or a co-sputtered metal silicide.

In certain embodiments of the current invention the metal gate layer (3) comprises at least one of the metals selected from the group of Mo, Ru, W, Al and co-sputtered Ni silicides. Advantageously, the thickness of the metal gate layer is lower than 10 nm.

In certain embodiments of the current invention the first strained conductive layer (4) comprises metal carbides, metal nitrides, metal silicides or combinations thereof.

In one embodiment of the current invention, the first strained conductive layer is selected from the group of TaxCy, WxCy, TixNy, TaxNy, TiAlN, TaAlN and combinations thereof, wherein x and y are real numbers 0<x, y≦1.

In another embodiment of the current invention the second strained conductive layer (10) is selected from the group of TaxCy, WxCy, TixNy, TaxNy, TiAlN, TaAlN and combinations thereof, wherein x and y are real numbers 0<x, y≦1.

In yet another embodiment of the current invention, the third strained conductive layer (7) comprises metal carbides, metal nitrides or combinations thereof.

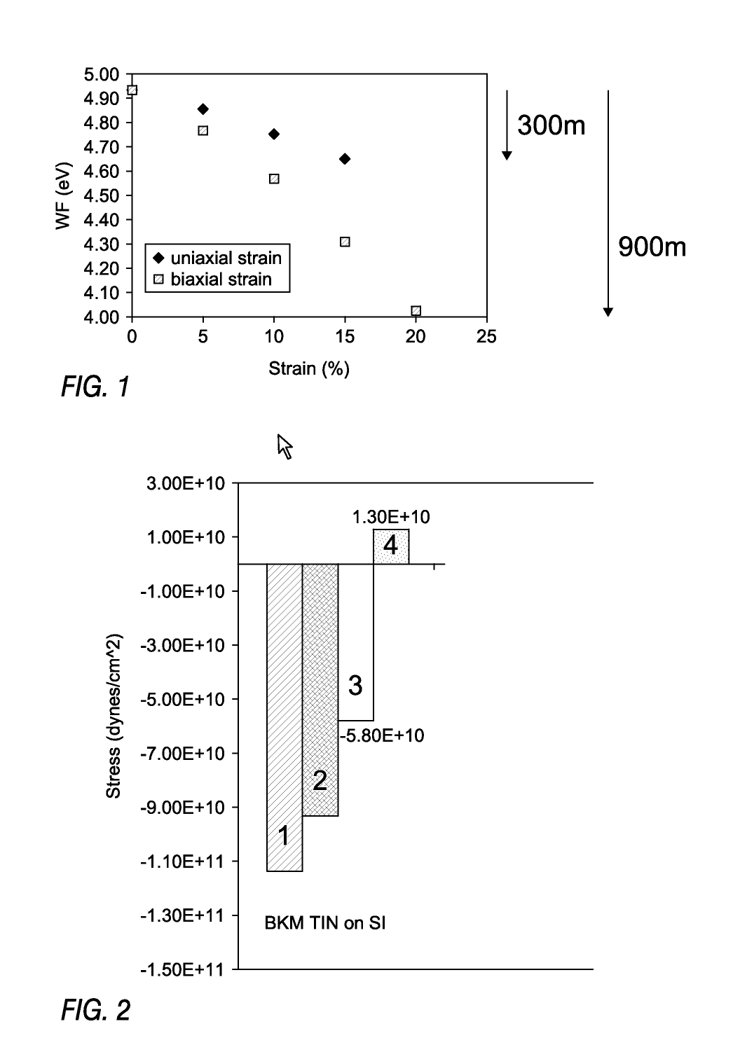

Simulation data have shown that when inducing a certain strain on pure Ta (110) layers a work function shift is obtained. It was surprisingly found that a strain of about 5-10% induces a work function (WF) shift of about 300 meV, which is enough to switch the device from e.g. a PMOS-type to a NMOS-type (FIG. 1). In an integration route, depending on the metal gate layer (3) of choice the amplitude and the sign (compressive or tensile) of strain needed to induce a similar pre-determined work function shift can be determined in advance.

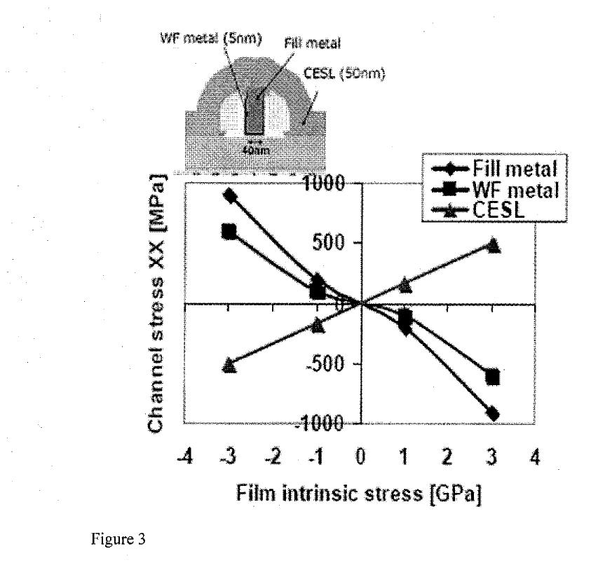

As shown in FIG. 2 different thermal treatments can further modulate the existing strain, leading to variations up to 11 GPa in TiN layers on Si depending on the temperature budget applied.

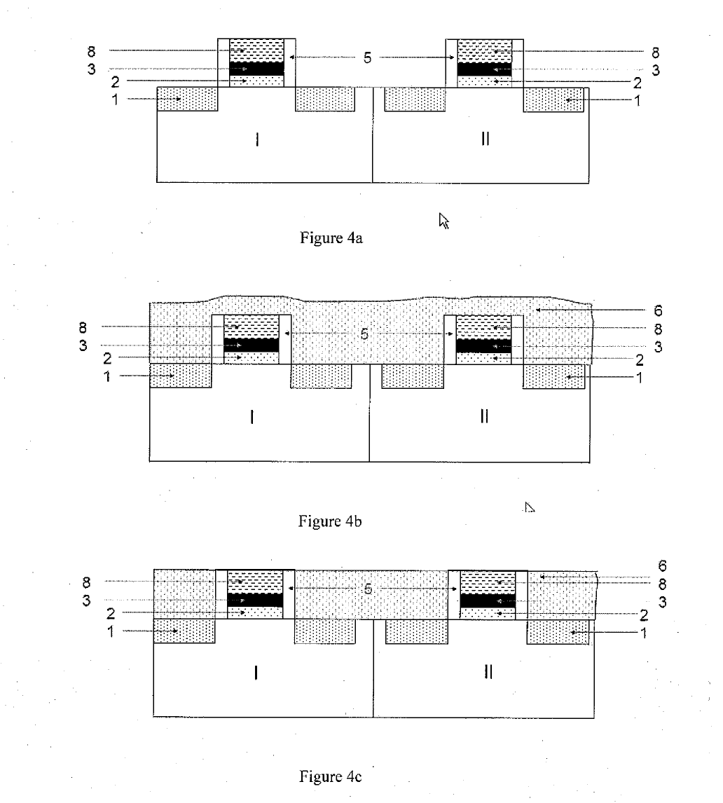

An additional benefit of employing strained metal layers as disclosed is the channel stress modulation as shown in FIG. 3.

FIG. 4 represents the different process steps in the manufacturing of the semiconductor device containing at least one strained conductive layer: (a) upon definition of the metal inserted polysilicon (MIPS) gate and the definition of the spacers; (b) dielectric deposition (6) prior to CMP (chemical mechanical polishing); (c) upon CMP of the dielectric layer (6); (d) upon selective removal of one of the polysilicon gates (8); (e) upon filling and CMP of the first strained conductive layer (4); (f) upon deposition of the third strained conductive layer (7) overlying a thin buffer dielectric layer (6′).

The metal gate layer (3) has an as deposited (intrinsic) work function which depends on the type metal, the thickness of the metal layer, the deposition method and the temperature budget applied. The metal gate layer can comprise Mo, Ru, W, Al, co-sputtered silicides (Ni and Si).

The gate dielectric (2) can comprise SiO2, SiON or any high-k material. The choice of high-k might have an influence on the stress behavior of the high-k/metal gate stack.

As shown in FIG. 4(a)-(e), a first strained conductive layer (4) is deposited upon the metal gate layer (3) by a replacement gate process, in order to avoid high temperature steps which may modify the strain.

The first strained conductive layer (4) can comprise metal carbides or metal nitrides like TaxCy, WxCy, TixNy, TaxNy. The material, the thickness and method of deposition of the first strained conductive layer are chosen in such way that a pre-determined level of strain is induced in the metal gate layer (3) and additionally the adhesion with the metal gate layer is compatible with further processing.

The replacement gate process further comprises dielectric (e.g. Si-oxide) deposition and dielectric chemical mechanical polishing (CMP) as shown schematically in FIG. 4(b and c), followed by polysilicon (8) gate wet removal in the second region while the first region is masked/protected (FIG. 4(d)) and the forming of the first strained conductive layer (4) as shown in FIG. 4(e).

In a particular embodiment, when the replacement gate is used on the PMOS region, a FUSI gate can be formed on the NMOS region.

Additionally, upon spacer definition a dielectric buffer layer (6) can be deposited followed by the deposition of a third strained conductive (TiN, W) layer.

FIG. 5 represents schematically PMOS metal gate with a first strained conductive layer (4) and NMOS metal gate with a second strained conductive layer (10).

The foregoing description details certain embodiments of the invention. It will be appreciated, however, that no matter how detailed the foregoing appears in text, the invention may be practiced in many ways. It should be noted that the use of particular terminology when describing certain features or aspects of the invention should not be taken to imply that the terminology is being re-defined herein to be restricted to including any specific characteristics of the features or aspects of the invention with which that terminology is associated.

While the above detailed description has shown, described, and pointed out novel features of the invention as applied to various embodiments, it will be understood that various omissions, substitutions, and changes in the form and details of the device or process illustrated may be made by those skilled in the technology without departing from the spirit of the invention.

What is claimed is:

1. A method of manufacturing a dual work function semiconductor device comprising:
providing a substrate with a first and a second region;
forming a gate dielectric overlying the first and the second region;
forming a metal gate layer overlying the gate dielectric on the first and the second region, the metal gate layer having a first as-deposited work function tunable upon inducing stress thereon;
selecting a first strain which induces a first pre-determined work function shift (ΔWF1) in the work function of the metal gate layer on the first region; and
selectively forming a first strained conductive layer overlying the metal gate layer on the first region, the first strained conductive layer exerting the selected first strain on the metal gate layer.

2. The method according to claim 1, wherein the selectively forming of a first strained conductive layer comprises:
depositing a layer of polysilicon overlying the metal gate layer on the first and the second region;
patterning the polysilicon, the metal gate layer, and the gate dielectric to form a gate structure on both the first and the second region;
forming dielectric spacers covering the sidewalls of the gate structure; and
performing a replacement gate process on the first region comprising replacing the polysilicon layer on the first region by the first strained conductive layer.

3. The method according to claim 1, wherein the selectively forming of a first strained conductive layer comprises:
depositing a first strained conductive layer overlying the metal gate layer on the first and the second region; and
selectively removing the first strained conductive layer over the metal gate layer on the second region.

4. The method according to claim 1, further comprising:
selecting a second strain which induces a second pre-determined work function shift (ΔWF2) in the first as deposited work function of the metal gate layer on the second region; and
selectively forming a second strained conductive layer overlying the metal layer on the second region, the second strained conductive layer exerting the selected second strain on the metal gate layer.

5. The method according to claim 4, wherein the metal gate layer has a mid-gap as-deposited work function and the first pre-determined work function shift (ΔWF1) and the second pre-determined work function shift (ΔWF2) have opposite signs with respect to the mid-gap.

6. The method according to claim 4, wherein the second strained conductive layer is selected from the group of TaxCy, WxCy, TixNy, TaxNy, TiAlN, TaAlN and combinations thereof, wherein x and y are real numbers 0<x, y≦1.

7. The method according to claim 2, further comprising:
selecting a third strain which induces a third pre-determined work function shift (ΔWF3) in the first as deposited work function of the metal gate layer on at least one of the first and the second region; and
selectively forming a third strained conductive layer overlying the gate structures and the spacers on at least one of the first and the second regions, respectively, the third strained conductive layer exerting the selected third strain on the gate structures comprising the metal gate layer.

8. The method according to claim 7, further comprising forming a dielectric layer in contact with the third strained conductive layer on both sides, thereby creating a dielectric-strained metal-dielectric stack.

9. The method according to claim 7, further comprising:
after depositing one of the first, the second, and the third strained conductive layers, performing a thermal treatment,
wherein the thermal treatment modifies the first, the second and/or the third strain exerted on the metal gate layer and thereby the first, the second and/or the third work function shift induced in the first (as deposited) work function of the metal gate.

10. The method according to claim 7, wherein the first and the third strained conductive layer are formed of same material.

11. The method according to claim 1, wherein the metal gate layer comprises a metal or a metal silicide.

12. The method according to claim 11, wherein the metal gate layer comprises at least one of the metals selected from the group of Mo, Ru, W, Al and co-sputtered Ni silicides.

13. The method according to claim 11, wherein the thickness of the metal gate layer is lower than about 10 nm.

14. The method according to claim 1, wherein the first strained conductive layer comprises metal carbides, metal nitrides, metal silicides or combinations thereof.

15. The method according to claim 14, wherein the first strained conductive layer is selected from the group of TaxCy, WxCy, TixNy, TaxNy, TiAlN, TaAlN and combinations thereof wherein x and y are real numbers 0<x, y≦1.

16. The method according to claim 14, wherein the method further comprises introducing one or more species selected from the group of C, N and O into the first strained conductive layer.

17. A dual work function semiconductor device comprising a first transistor having a work function and a second transistor having a different work function, formed by the method of claim 1.

18. A dual work function semiconductor device according to claim 17, wherein a first transistor is a NMOS transistor and a second transistor is a PMOS transistor.

19. A method of manufacturing a dual work function semiconductor device comprising:
providing a gate dielectric overlying a first and a second region in a substrate and a metal layer overlying the gate dielectric on the first and the second region, the metal gate layer having an as-deposited work function; and
forming a first strained conductive layer overlying the metal gate layer on the first region, the first strained conductive layer being selected to exert strain on the metal gate layer thus inducing a first pre-determined work function shift in the work function of the metal gate layer on the first region.

20. The method of claim 19, further comprising forming a second strained conductive layer overlying the metal gate layer on the second region, the second strained conductive layer being selected to exert strain on the metal gate layer thus inducing a second pre-determined work function shift in the work function of the metal gate layer on the second region.

21. The method of claim 20, wherein the first pre-determined work function shift is selected to be different from the second predetermined work function shift.
